(19) United States
(12) Patent Application Publication
(10) Pub. No.: US 2025/0155506 A1
(43) Pub. Date: May 15, 2025

(54) BATTERY MANAGEMENT APPARATUS AND OPERATING METHOD THEREOF

(71) Applicant: LG ENERGY SOLUTION, LTD., Seoul (KR)

(72) Inventor: Young Jin KIM, Daejeon (KR)

(73) Assignee: LG ENERGY SOLUTION, LTD., Seoul (KR)

(21) Appl. No.: 18/723,201

(22) PCT Filed: Nov. 22, 2022
(86) PCT No.: PCT/KR2022/018489

§ 371 Date: Jun. 21, 2024

(30) Foreign Application Priority Data
Dec. 23, 2021 (KR) 10-2021-0186533

(51) Int. Cl. G01R 31/36; G01R 31/388

(52) U.S. Cl. CPC G01R 31/3648; G01R 31/388

(57) ABSTRACT

Discussed is a battery management apparatus that includes a voltage measuring unit configured to measure a voltage of a battery cell and a controller configured to sample raw data regarding the voltage of the battery cell in a designated unit to convert the raw data into original data in a monotonically increasing or monotonically decreasing form, smooth the original data into smoothed data by using an optimal smoothing parameter determined according to a set algorithm, and convert the smoothed data into a differential signal. Thus, in a pre-processing process for converting voltage data of a battery into a differential signal, an optimal smoothing parameter may be determined, which enables proper fitting with the original data while reducing fluctuation of a curve of a smoothed differential signal.

### CROSS-REFERENCE TO RELATED APPLICATION

This application claims priority to and the benefit of Korean Patent Application No. 10-2021-0186533 filed in the Korean Intellectual Property Office on Dec. 23, 2021, the entire contents of which are incorporated herein by reference.

### TECHNICAL FIELD

Embodiments disclosed herein relate to a battery management apparatus and an operating method thereof.

### BACKGROUND ART

Recently, research and development of secondary batteries have been actively performed. Herein, the secondary batteries, which are chargeable/dischargeable batteries, may include all of conventional nickel (Ni)/cadmium (Cd) batteries, Ni/metal hydride (MH) batteries, etc., and recent lithium-ion batteries. Among the secondary batteries, a lithium-ion battery has a much higher energy density than those of the conventional Ni/Cd batteries, Ni/MH batteries, etc. Moreover, the lithium-ion battery may be manufactured to be small and lightweight, such that the lithium-ion battery has been used as a power source of mobile devices. In addition, the lithium ion battery is attracting attention as a next-generation energy storage medium as a usage range thereof is expanded to a power source of electric vehicles. Furthermore, the secondary battery is generally used as a battery pack including a battery module where a plurality of battery cells are connected to one another in series and/or in parallel. Battery packs may be managed and controlled by a battery management apparatus in terms of their states and operations.

In such secondary batteries, an abnormal voltage drop phenomenon suspected to be an internal short-circuit is sometimes observed during a charge period. To detect this phenomenon, a differential signal regarding a voltage of a battery may be used. At this time, smoothing processing is performed to convert voltage data of the battery into the differential signal, and to obtain an optimal result, it is necessary to determine a smoothing parameter capable of achieving proper fitting with original data while low curve shaking of the differential signal.

### DISCLOSURE

### Technical Problem

Embodiments disclosed herein aim to provide a battery management apparatus and an operating method thereof in which in a pre-processing process for converting voltage data of a battery into a differential signal, an optimal smoothing parameter is determined according to a set algorithm and the differential signal is obtained using the parameter.

Embodiments disclosed herein aim to provide a battery management apparatus and an operating method thereof in which an abnormal voltage drop phenomenon caused by an internal short-circuit during charge of a battery may be detected using a differential signal regarding a voltage of the battery and purposes such as quantification of battery deterioration, identification of abnormal deterioration, etc., may be further achieved.

Technical problems of the embodiments disclosed herein are not limited to the above-described technical problems, and other unmentioned technical problems would be clearly understood by one of ordinary skill in the art from the following description.

### Technical Solution

A battery management apparatus according to an embodiment includes a voltage measuring unit configured to measure a voltage of a battery cell and a controller configured to sample raw data regarding the voltage of the battery cell in a designated unit to convert the raw data into original data in a monotonically increasing or monotonically decreasing form, smooth the original data by using an optimal smoothing parameter determined according to a set algorithm, and convert the smoothed data into a differential signal.

In the battery management apparatus according to an embodiment, the controller may be further configured to determine the optimal smoothing parameter by using an algorithm of minimizing a cost function.

In the battery management apparatus according to an embodiment, the controller is further configured to obtain a differential signal set corresponding to the original data smoothed using at least one smoothing parameter of preset smoothing parameters and calculate the cost function based on a curve length of the differential signal set and a difference between the original data and the differential signal set.

In the battery management apparatus according to an embodiment, the controller may be further configured to calculate a cost function value corresponding to the at least one smoothing parameter by multiplying a first variable that is a value obtained by linearly integrating a differential signal corresponding to the at least one smoothing parameter in a designated section by a second variable that is a root mean square (RMS) value of the difference between the original data and the differential signal corresponding to the at least one smoothing parameter.

In the battery management apparatus according to an embodiment, the controller may be further configured to determine a smoothing parameter that minimizes a corresponding cost function value among the preset smoothing parameters.

In the battery management apparatus according to an embodiment, each of the preset smoothing parameters may be a smoothing parameter in which a peak value of a corresponding differential signal does not exceed a designated value.

In the battery management apparatus according to an embodiment, the controller may be further configured to classify capacity values of the battery cell having a same voltage magnitude and calculate an average value of the capacity values of the battery cell for each voltage magnitude to perform sampling with respect to the voltage of the battery cell.

In the battery management apparatus according to an embodiment, the controller may be further configured to perform smoothing of the original data by using a smoothing algorithm to which a hyper parameter is applied such that a slope of the voltage of the battery cell satisfies a continuity between adjacent data points.

The battery management apparatus according to an embodiment may further include an abnormality diagnosing unit configured to calculate a statistical value for the differential signal and diagnose that an abnormality of the battery cell occurs when the statistical value for the differential signal is equal to or greater than a preset reference value.

In the battery management apparatus according to an embodiment, the differential signal may be a voltage-capacity differential signal or a voltage-time differential signal of the battery cell.

An operating method of a battery management apparatus according to an embodiment includes measuring a voltage of a battery cell, sampling raw data regarding the voltage of the battery cell in a designated unit to convert the raw data into original data in a monotonically increasing or monotonically decreasing form, smoothing the original data into smoothed data by using an optimal smoothing parameter determined according to a set algorithm, and converting the smoothed data into a differential signal.

In the operating method of the battery management apparatus according to an embodiment, the smoothing of the original data may include determining the optimal smoothing parameter by using an algorithm of minimizing a cost function.

In the operating method of the battery management apparatus according to an embodiment, the determining of the optimal smoothing parameter may include smoothing the original data by using at least one smoothing parameter of preset smoothing parameters, obtaining a differential signal set corresponding to each smoothing parameter based on the original smoothed data, and calculating the cost function based on a curve length of the differential signal set and a difference between the original data and the differential signal set.

In the operating method of the battery management apparatus according to an embodiment, the calculating of the cost function may include calculating a cost function value corresponding to the at least one smoothing parameter by multiplying a first variable that is a value obtained by linearly integrating a differential signal corresponding to the at least one smoothing parameter in a designated section by a second variable that is a root mean square (RMS) value of a difference between the original data and the differential signal corresponding to the at least one smoothing parameter.

In the operating method of the battery management apparatus according to an embodiment, the determining of the optimal smoothing parameter may further include determining a smoothing parameter that minimizes a corresponding cost function value among the preset smoothing parameters.

In the operating method of the battery management apparatus according to an embodiment, each of the preset smoothing parameters may be a smoothing parameter in which a peak value of a corresponding differential signal does not exceed a designated value.

In the operating method of the battery management apparatus according to an embodiment, the sampling of the raw data regarding the voltage in the designated unit to convert the raw data into the original data in the monotonically increasing or monotonically decreasing form may include classifying capacity values of the battery cell having a same voltage magnitude and calculating an average value of the capacity values of the battery cell for each voltage magnitude to perform sampling with respect to the voltage of the battery cell.

In the operating method of the battery management apparatus according to an embodiment, the smoothing of the original data may include performing smoothing by using a smoothing algorithm to which a hyper parameter is applied such that a slope of the voltage of the battery cell satisfies a continuity between adjacent data points.

The operating method of the battery management apparatus according to an embodiment may further include calculating a statistical value for the differential signal and diagnosing that an abnormality of the battery cell occurs when the statistical value for the differential signal is equal to or greater than a preset reference value.

In the operating method of the battery management apparatus according to an embodiment, the differential signal may be a voltage-capacity differential signal or a voltage-time differential signal of the battery cell.

### Advantageous Effects

According to an embodiment, in a pre-processing process for converting data regarding a voltage of a battery into a differential signal, an optimal smoothing parameter may be determined, which enables proper fitting with original data while reducing fluctuation of a curve of a smoothed differential signal.

Moreover, it is possible to obtain a differential signal regarding a voltage of a battery (e.g., a voltage-capacity differential signal, a voltage-time differential signal, etc.) by using an optimal smoothing parameter, accurately and easily detect an abnormal voltage drop phenomenon caused by an internal short-circuit of the battery based on the differential signal, and achieve a purpose such as battery deterioration quantification, abnormal deterioration identification, or the like.

Moreover, various effects recognized directly or indirectly from the disclosure may be provided.

### DESCRIPTION OF DRAWINGS

In order to more clearly describe technical solutions of embodiments disclosed herein or the prior art, the drawings required in the description of the embodiments are briefly introduced below. It should be understood that the following drawings are for the purpose of explaining the embodiments of the present specification and not for limiting purposes. In addition, representations of some components in the drawings may be exaggerated or omitted for clarity of explanation.

FIG. 1 is a block diagram showing a configuration of a battery control system.

FIG. 2 is a block diagram showing a configuration of a battery management apparatus according to an embodiment.

FIG. 3A is a graph showing raw data of a measured voltage of a battery, and FIG. 3B is a graph showing a differential signal of voltage raw data of FIG. 3A.

FIG. 4 is a diagram showing a method of performing sampling to remove a redundant signal of battery voltage data.

FIG. 5A is a graph showing a result of performing pre-processing on battery voltage data through sampling and smoothing, and FIG. 5B is a graph showing a differential abstract shape of battery voltage data for each pre-processing stage.

FIG. 6A is a graph showing a change of a signal form with respect to original data of a voltage-capacity differential signal and a smoothing parameter value, and FIG. 6B is a graph showing a change of a curve length L of a differential signal and a difference rms from original data with respect to a smoothing parameter value.

FIG. 7A is a graph showing a change in a cost function (L*rms) with respect to a smoothing parameter value for sampling at 1-second intervals, and FIG. 7B is a graph showing a change in a cost function (L*rms) with respect to a smoothing parameter value for sampling at 60-second intervals.

FIG. 8 is a flowchart showing an operating method of a battery management apparatus according to an embodiment.

FIG. 9 is a flowchart showing a detailed process of an operation of smoothing data in an operating method of a battery management apparatus according to an embodiment.

FIG. 10 is a flowchart showing an operating method of a battery management apparatus according to another embodiment.

### MODE FOR INVENTION

Hereinafter, embodiments disclosed in this document will be described in detail with reference to the exemplary drawings. In adding reference numerals to components of each drawing, it should be noted that the same components are given the same reference numerals even though they are indicated in different drawings. In addition, in describing the embodiments disclosed in this document, when it is determined that a detailed description of a related known configuration or function interferes with the understanding of an embodiment disclosed in this document, the detailed description thereof will be omitted.

Although terms used herein are selected with general terms popularly used at present under the consideration of functions in the disclosure, the terms may vary according to the intention of those of ordinary skill in the art, custom, or introduction of new technology. In addition, in a specific case, the applicant voluntarily may select terms, and in this case, the meaning of the terms may be disclosed in a corresponding description part of the present specification. Therefore, the terms used herein should be defined not by the simple names of the terms but by the substantial meaning of the terms and the contents throughout the disclosure.

Terms defined in the present disclosure are used for only describing a specific exemplary embodiment and may not have an intention to limit the scope of other exemplary embodiments. It is to be understood that the singular forms include plural references unless the context clearly dictates otherwise.

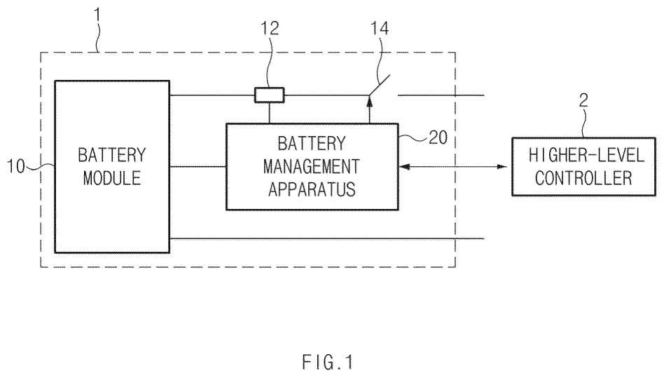

FIG. 1 is a block diagram showing a configuration of a battery control system according to an embodiment, schematically showing a battery control system including a battery pack 1 and a higher-level controller 2 included in a higher-level system. The battery pack 1 may be used for an energy storage system, a vehicle, etc., without being limited to such a purpose.

Referring to FIG. 1, the battery pack 1 may include a battery module 10 that includes one or more chargeable/dischargeable battery cells, a switching element 14 serially connected to a positive (+) terminal side or a negative (−) terminal side of the battery module 10 to control a charging/discharging current flow of the battery module 10, and a battery management apparatus 20 for control and management to prevent over-charge and over-discharge by monitoring voltage, current, temperature, etc., of the battery pack 1.

Herein, as the switching element 14 which is a semiconductor switching element for controlling a current flow for charge or discharge of the battery module 10, for example, at least one metal oxide semiconductor field effect transistor (MOSFET) may be used.

The battery management apparatus 20 may measure or calculate a voltage and a current of a gate, a source, a drain, etc., of the semiconductor switching element to monitor the voltage, the current, the temperature, etc., of the battery pack 1, and measure the current, the voltage, the temperature, etc., of the battery pack 1 by using a sensor 12 provided adjacent to the semiconductor switching element 14.

The battery management apparatus 20 may include a plurality of terminals as an interface for receiving measured values of various parameters described above, a circuit connected to the terminals to process received values, etc. The battery management apparatus 20 may control ON/OFF of the switching element 14, and may be connected to the battery module 10 to monitor a state of the battery module 10.

The higher-level controller 2 may transmit a control signal regarding the battery module to the battery management apparatus 20. Thus, the battery management apparatus 20 may be controlled in terms of an operation thereof based on a signal applied from the higher-level controller.

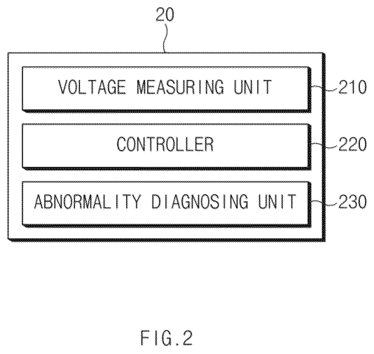

FIG. 2 is a block diagram showing a configuration of a battery management apparatus according to an embodiment.

Referring to FIG. 2, the battery management apparatus 20 according to an embodiment may include a voltage measuring unit 210 and a controller 220, and selectively, may further include an abnormality diagnosing unit 230.

The voltage measuring unit 210 may measure a voltage of a battery cell to obtain voltage data. For example, the voltage measuring unit 210 may be configured to measure voltages of one or more battery cells included in the battery module 10 at specific time intervals through the sensor 12 included in the battery pack 1 of FIG. 1.

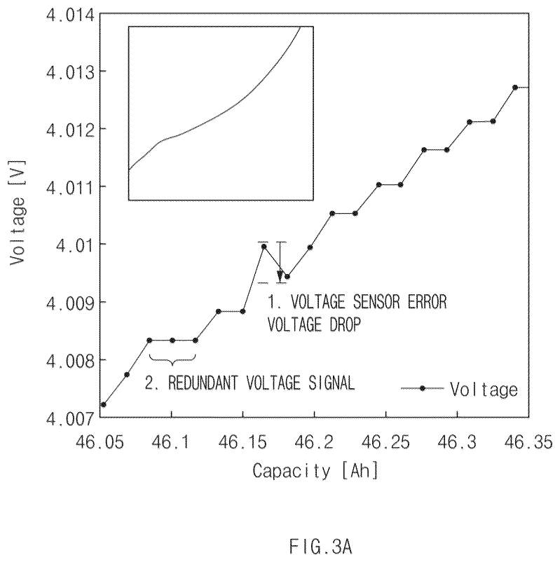

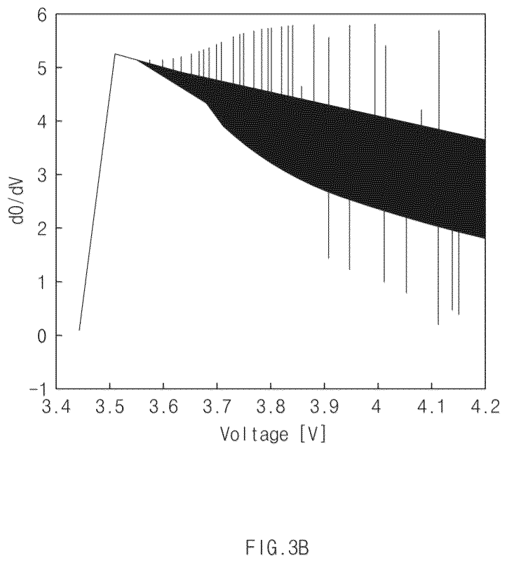

The controller 220 may pre-process voltage data (e.g., a voltage signal over time) of a battery cell to convert a voltage of the battery cell to be differentiable in a certain section. As illustrated in a graph of FIG. 3A, differential analysis of generally measured voltage data of the battery may be impossible due to a redundant signal, a discontinuous section, etc. Thus, the controller 220 may pre-process the voltage data of the battery cell before converting the differential signal to convert the voltage of the battery cell to be differentiable in a preset section.

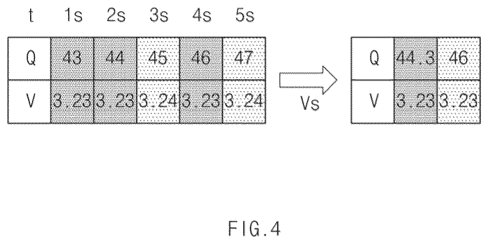

More specifically, the controller 220 may convert the voltage of the battery cell into data in the form of a monotonic increase (i.e., an increase without a decrease in a specific section) or a monotonic decrease (i.e., a decrease without an increase in a specific section). For example, the controller 220 may perform sampling with respect to a voltage by classifying capacity values Q of battery cells having an equal voltage magnitude V and calculating an average value of capacity values of battery cells for each voltage magnitude. This will be described later with reference to FIG. 4.

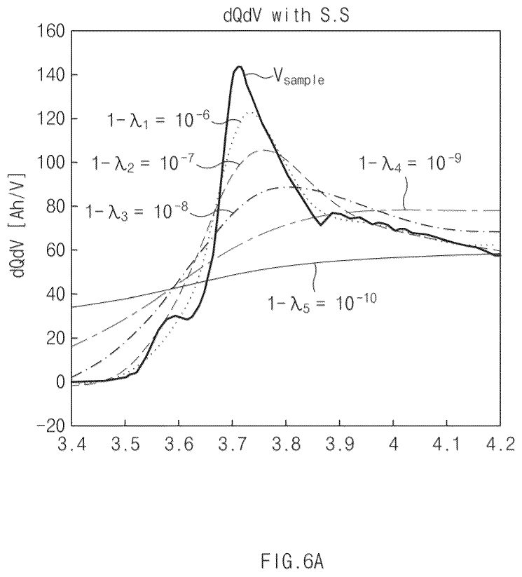

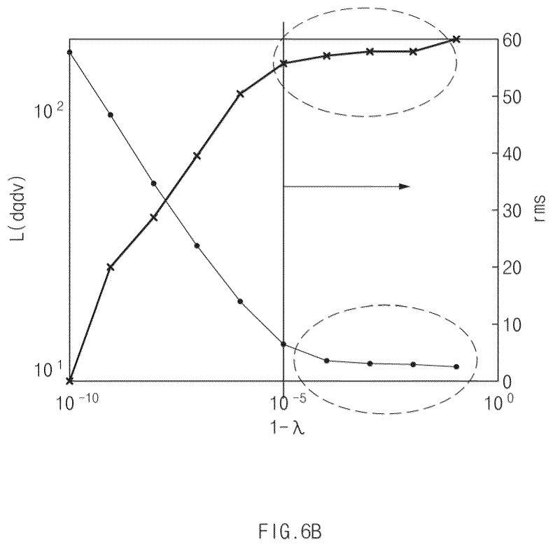

The controller 220 may convert a curve of a slope of voltage data of a battery cell into a smooth shape through smoothing of sampled data. In this way, continuity between adjacent data and voltage data may be differentiable in a specific section. According to a smoothing parameter value applied, the smoothness of the slope curve may vary with the smoothing parameter to be applied. For example, in case of a smoothing scheme according to an embodiment, the curve may become smooth as the parameter value increases, increasing a difference from original data, and it becomes closer to the original data as the parameter value decreases, increasing the fluctuation of the curve. Thus, when an optimal smoothing parameter is determined, variables in such a trade-off relationship need to be considered properly. This will be described later with reference to FIGS. 6A and 6B.

The controller 220 may convert voltage data of a battery cell, which has been pre-processed (sampled and smoothed) into a differential signal. In this case, the controller 220 may calculate a differential signal (e.g., dQ/dV, dV/dQ, dV/dt, etc.) regarding a capacity and a voltage of a battery cell. According to an embodiment, to determine an optimal parameter, the controller 220 may obtain a differential signal set corresponding to each of at least one preset smoothing parameters and determine an optimal smoothing parameter based on two or more variables (e.g., a smoothness of a differential signal curve, a difference from original data, etc.) for the differential signal set.

The abnormality diagnosing unit 230 may calculate a statistical value for the converted differential signal. In this case, the statistical value of the differential signal calculated by the controller 220 is intended to identify the abnormal behavior of the battery in a sliding window (or moving window) manner. For example, the statistical value of the differential signal may include a standard deviation.

The abnormality diagnosing unit 230 may diagnose abnormality of the battery cell based on the differential signal converted in the controller 220. More specifically, the abnormality diagnosing unit 230 may diagnose that an abnormal voltage drop occurs in the battery cell when the statistical value of the differential signal of a battery voltage is equal to or greater than a preset reference value.

The abnormality diagnosing unit 230 may diagnose abnormality of the battery cell in the sliding window manner for the statistical value of the differential signal of the battery voltage. As such, when the abnormality diagnosing unit 230 diagnoses abnormality of the battery cell in the sliding window manner, a size of a window may be set by a user at random. In this case, the statistical value of the differential signal of the battery voltage may include a standard deviation.

Although not shown, the battery management apparatus 20 according to an embodiment may further include a memory unit and an alarming unit. In this case, the memory unit may store a voltage of the battery cell, measured by the voltage measuring unit 210, and a differential signal of the voltage, calculated by the controller 220. In addition, the alarming unit may generate a warning alarm when it is determined by the abnormality diagnosing unit 230 that abnormality occurs in the battery cell. In this case, the warning alarm may be provided in the form of a message on a display unit (not shown) connected to the battery control system, or light or a sound signal.

Although not shown, an additional device or system capable of executing a function such as battery deterioration quantification, abnormality deterioration identification, etc., may be included as well as the abnormality diagnosing unit 230.

Hereinbelow a pre-processing process for converting voltage data into a differentiable signal will be described in detail with reference to the drawings.

According to an embodiment, the controller 220 may sample data regarding a voltage of a battery cell in a designated unit to convert the data into data in a monotonically increasing or monotonically decreasing form.

FIG. 3A is a graph showing raw data of a measured voltage of a battery, and FIG. 3B is a graph showing a differential signal of voltage raw data of FIG. 3A. In this case, a horizontal axis of FIG. 3A indicates a capacity Ah of a battery and a vertical axis indicates a measured voltage V of the battery. In addition, a horizontal axis of FIG. 3B indicates the voltage V of the battery and a vertical axis indicates a differential signal dQ/dV regarding a capacity and a voltage of the battery.

Referring to FIG. 3A, measured voltage data of the battery may include noise, a redundant voltage signal, etc., due to an error of a voltage sensor. Thus, as shown in FIG. 3B, it may be difficult to analyze a differential signal with respect to voltage or current data.

FIG. 4 is a diagram showing a method of performing sampling to remove a redundant signal of battery voltage data. Referring to FIG. 4, measured data of each of a capacity and a voltage of a battery with respect to time is shown. Herein, in sections where a capacity of the battery is 43 Ah, 44 Ah, and 46 Ah, a voltage is equal to 3.23 V, and in sections where the capacity of the battery is 45 Ah and 47 Ah, the voltage is equal to 3.24 V. Thus, as shown in FIGS. 3A and 3B, a redundant signal may occur in voltage data, making differential analysis impossible.

In such a case, for capacity and voltage data of the battery, capacity values of the battery may be classified based on a voltage of a particular magnitude, and an average value thereof may be calculated to sample battery voltage data. For example, as shown in FIG. 4, based on redundant battery voltages of 3.23 V and 3.24 V, an average value of capacity values corresponding to the respective voltages may be calculated. For example, for a voltage of 3.23 V, an average value of 44.3 Ah of battery capacities of 43 Ah, 44 Ah, and 46 Ah may be determined as a capacity value, and for a voltage of 3.24 V, an average value of 46 Ah of the battery capacities 45 Ah and 47 Ah may be determined as the capacity value.

As such, the controller 220 according to an embodiment may sample voltage data in a designated unit to convert voltage data into data in a monotonically increasing or monotonically decreasing form based on a measured voltage.

According to an embodiment, the controller 220 may perform smoothing such that the sampled data is differentiable in a preset section.

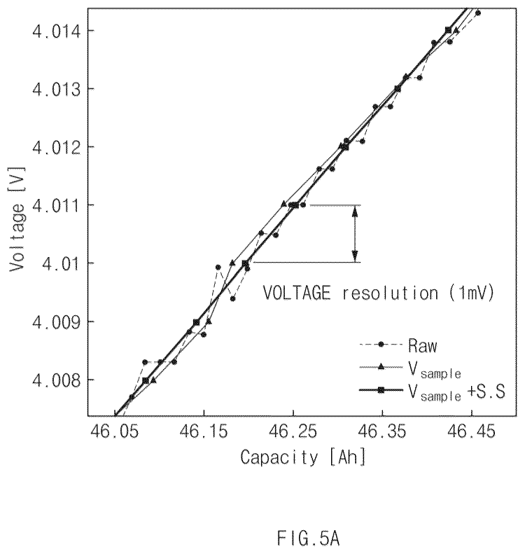

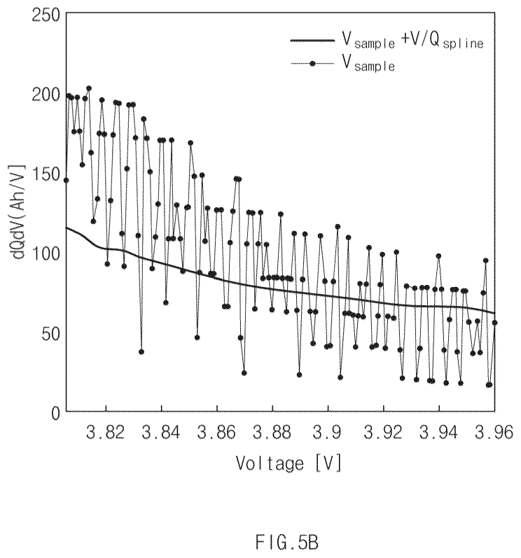

FIG. 5A is a graph showing a result of performing pre-processing on battery voltage data through sampling and smoothing, and FIG. 5B is a graph showing a differential abstract shape of battery voltage data for each pre-processing stage. In this case, a horizontal axis of FIG. 5A indicates a capacity Ah of a battery and a vertical axis indicates a measured voltage V of the battery. In addition, a horizontal axis of FIG. 5B indicates the voltage V of the battery and a vertical axis indicates a differential signal Ah/V regarding a capacity and a voltage of the battery.

As shown in FIG. 5A, a redundant signal and noise occur in raw data of a voltage, but voltage data sampled according to FIG. 4 appears in a monotonically increasing form.

Meanwhile, even when sampling is performed on raw data of a voltage, a section where differentiation is impossible may occur due to a slope difference between adjacent data. In this regard, referring to FIG. 5B, when sampling is simply performed on raw data of a voltage, a value of a differential signal may not be completely represented.

Thus, the controller 220 may smooth the sampled voltage data such that the slope of the voltage data of the battery satisfies continuity. According to an embodiment, a smoothing spline (S.S) scheme may be applied, and a calculation formula of the SS may be expressed as below.

$${\sum }_{i = 1}^{n} {\{ {Y}_{i} - \hat{f} ( {x}_{i} ) \}}^{2} + λ \int {{\hat{f}}^{n} ( x )}^{2} dx$$

Through the S.S calculation formula, it is possible to prevent the slope of the sampled voltage data from rapidly changing and convert the same into a continuous curve. As a smoothing parameter λ increases, the curve may become smoother. For example, λ may be 0.001 V and 0.01 Q, respectively.

Meanwhile, a data pre-processing method according to embodiments disclosed herein may use any other data smoothing algorithms to which a hyper parameter (a variable input by a user in modeling) is applied, than the S.S scheme. An optimal smoothing parameter applied to each S.S scheme may be determined according to an embodiment described below.

Referring back to FIG. 5A, when S.S is applied to the sampled voltage data, the voltage data may be converted into a differentiable form while satisfying continuity of the slope of the voltage data. As shown in FIG. 5B, for a differential signal to which S.S is performed in addition to sampling, a graph appears smooth without noise.

As described above, the smoothness of the differential signal curve varies with the smoothing parameter λ, and the curve may become smooth as the parameter value increases, increasing a difference from original data, and it becomes closer to the original data as the parameter value decreases, increasing the fluctuation of the curve. Thus, disclosed embodiments provide an algorithm for determining an optimal smoothing parameter by using a cost function considering two elements in a tradeoff relationship.

According to an embodiment, the controller 220 may smooth data by applying at least one preset parameters (e.g., λ₁, λ₂, . . . , λ₅), and obtain a differential signal set corresponding to each smoothing parameter. Herein, each of the at least one smoothing parameters may be a smoothing parameter in which a peak value of a corresponding differential signal does not exceed a designated value.

FIG. 6A is a graph showing a change of a signal form with respect to original data Vₛₐₘₚₗₑ of a voltage-capacity differential signal dQ/dV and the smoothing parameters λ₁, λ₂, . . . , λ₅, according to an embodiment. Referring to FIG. 6A, it may be seen that as the smoothing parameter λ increases (i.e., as (1−λ) decreases to 10⁻⁶, 10⁻⁷, . . . , 10⁻¹⁰), the curve becomes smooth, but a difference from the original data increases.

The cost function may be calculated for each differential signal set, simultaneously considering the smoothness of the curve and a difference from the original data. According to an embodiment, the smoothness of the curve may be represented as a first variable that is a value obtained by linearly integrating the differential signal in a certain section (e.g., a section where a voltage magnitude is 3.4 V to 4.2 V), and a difference from the original data may be represented as a second variable that is a root mean square (RMS) value of a difference between the original data and the differential signal. That is, as the smoothing parameter value increases (1−λ decreases), the curve of the differential signal becomes smooth and the first variable indicating the length of the curve decreases. On the other hand, as the smoothing parameter value increases (1−λ decreases), the second variable indicating the difference from the original data increases.

FIG. 6B is a graph showing a change of a curve length L of a differential signal and a difference rms from original data with respect to a smoothing parameter value λ. Referring to FIG. 6B, it may be seen that as the smoothing parameter λ increases (i.e., as (1−λ) decreases to 10⁻⁶, 10⁻⁷, . . . , 10⁻¹⁰), the length L of the curve decreases and the difference rms from the original data increases.

According to an embodiment, the controller 220 may calculate a cost function value corresponding to each smoothing parameter by multiplying the first variable (the curve length of the differential signal) by the second variable (the difference rms from the original data). Among the smoothing parameters (e.g., λ₁, λ₂, . . . , λ₅), a smoothing parameter that minimizes a corresponding cost function value may be determined as an optimal smoothing parameter. The optimal smoothing parameter determined considering the cost function may mean a parameter value that enables proper fitting with the original data while reducing the fluctuation of the generated data (e.g., the differential signal such as dQ/dV, dV/dQ, dV/dt, etc.) curve.

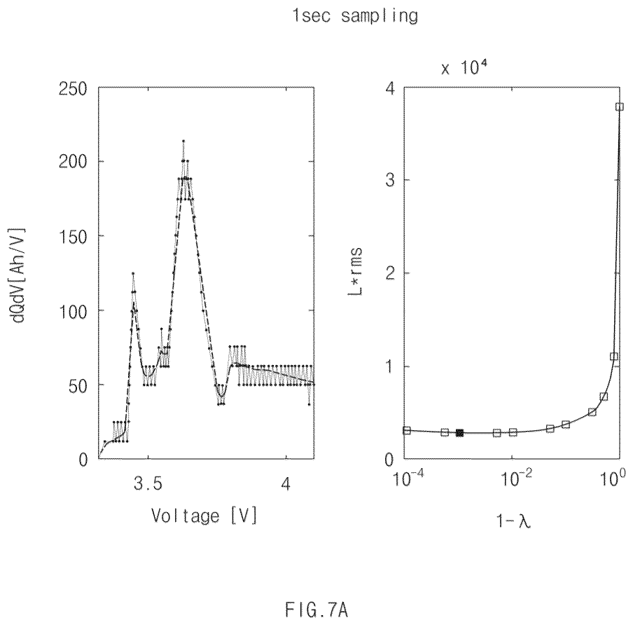

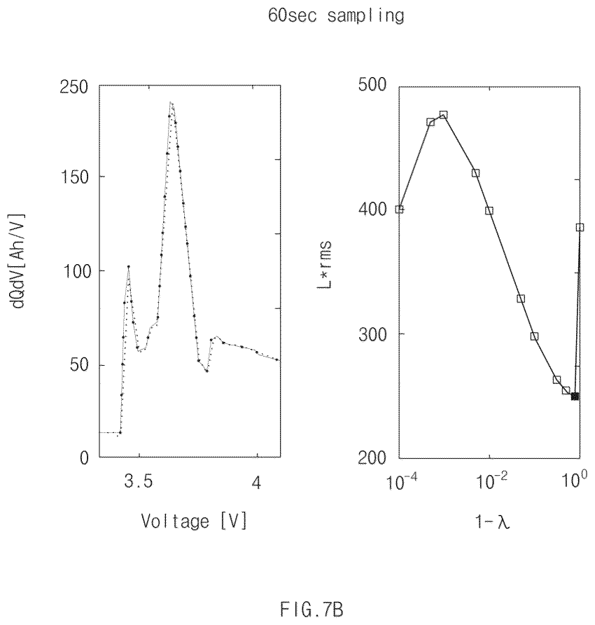

FIG. 7A is a graph showing a change in a cost function (L*rms) with respect to a smoothing parameter value for sampling at 1-second intervals, and FIG. 7B is a graph showing a change in a cost function (L*rms) with respect to a smoothing parameter value for sampling at 60-second intervals. It may be seen that a smoothing parameter value that minimizes a cost function varies with sampling variation. That is, different smoothing parameters are applied depending on a measurement environment, and an optimal smoothing parameter may be determined by applying consistent standards rather than empirical implementation.

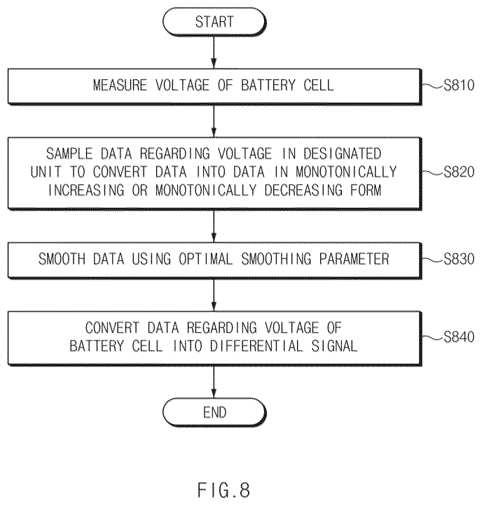

FIG. 8 is a flowchart showing an operating method of a battery management apparatus according to an embodiment. A structure and components of the battery management structure are as described above with reference to FIG. 1.

Referring to FIG. 8, in the operating method of the battery management apparatus according to an embodiment, first, operation S810 of measuring a voltage of a battery cell is performed. For example, the voltage measuring unit 210 of the battery management apparatus 20 may obtain voltage data by measuring the voltage of the battery cell through the provided sensor 12 (see FIGS. 1 and 2).

Next, operation S820 of sampling voltage data in a designated unit for conversion into data in a monotonically increasing or monotonically decreasing form is performed. The controller 220 of the battery management apparatus 20 may sample the voltage data of the battery cell measured by the voltage measuring unit 210 for conversion into data in a form of increasing without decreasing (monotonically increasing) in a certain section or decreasing without increasing (monotonically decreasing) in a certain section (see FIG. 5A).

According to a detailed embodiment, operation S820 may include an operation of classifying capacity values of the battery cell having the same voltage magnitude and calculating an average value of the capacity values of the battery cell for each voltage magnitude to perform sampling with respect to the voltage (see FIG. 4).

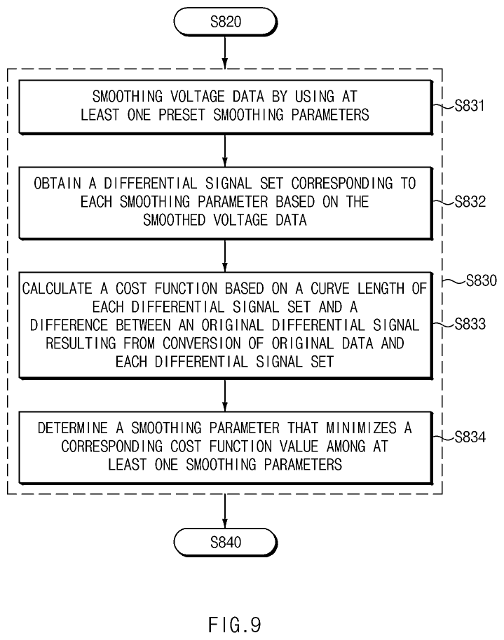

Next, operation S830 of smoothing data by using an optimal smoothing parameter may be performed. The controller 220 may be configured to satisfy continuity between adjacent data through a smoothing process of converting a curve of a slope of the sampled data into a smooth form. A detailed process of operation 830 will be described later with reference to FIG. 9.

Next, operation S840 of converting the data regarding the voltage of the battery cell into a differential signal may be performed. The controller 220 may convert the voltage data of the battery cell on which pre-processing operations S820 and S830 have been completed into a differential signal (e.g., the voltage-capacity differential signal dQ/dV). The voltage-capacity differential signal may be used to detect the abnormal voltage drop phenomenon of the battery cell.

FIG. 9 is a flowchart showing a detailed process of an operation of determining an optimal smoothing parameter using a set algorithm and smoothing data using the same, in an operating method of a battery management apparatus according to an embodiment.

Referring to FIG. 9, operation S831 of smoothing voltage data by using at least one preset smoothing parameters may be performed. According to an embodiment, each of the at least one smoothing parameters may be a smoothing parameter in which a peak value of a corresponding differential signal does not exceed a designated value.

Then, operation S832 of obtaining a differential signal set corresponding to each smoothing parameter based on the smoothed voltage data may be performed. In this case, the smoothness of each differential signal curve varies with the smoothing parameter, and the curve may become smooth as the parameter value increases, increasing a difference from original data, and it becomes closer to the original data as the parameter value decreases, increasing the fluctuation of the curve.

Next, operation S833 of calculating a cost function based on a curve length of each differential signal set and a difference between an original differential signal resulting from conversion of original data and each differential signal set may be performed. The controller 220 may calculate a cost function by simultaneously considering the smoothness of the differential signal curve and the difference from the original data.

According to an embodiment, operation S833 of calculating the cost function may include an operation of calculating a cost function value corresponding to the smoothing parameter by multiplying a first variable that is a value obtained by linearly integrating the differential signal corresponding to the smoothing parameter in a designated section by a second variable that is an RMS value of a difference between the original data and the differential signal corresponding to the smoothing parameter.

Thereafter, operation S834 of determining a smoothing parameter that minimizes a corresponding cost function value among at least one smoothing parameters may be performed. As such, the optimal smoothing parameter determined considering the cost function may mean a parameter value that enables proper fitting with the original data while reducing the fluctuation of the generated data (e.g., dQ/dV data) curve.

In this way, by using a random smoothing algorithm (e.g., a smoothing spline) to which a hyper parameter is applied, the slope of the voltage of the battery cell may satisfy continuity.

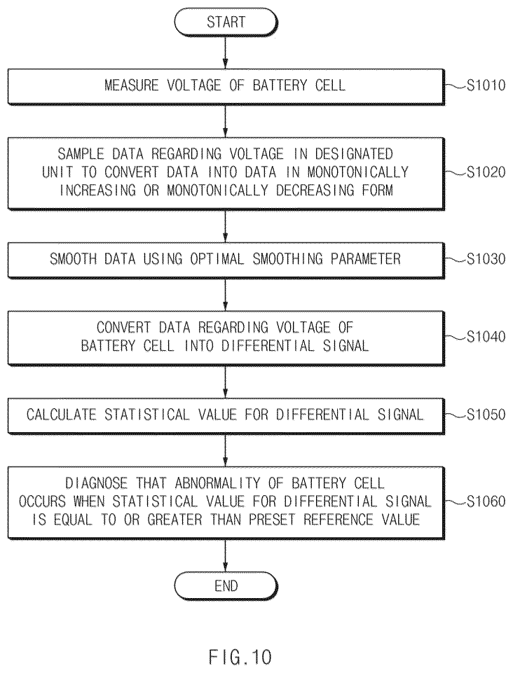

FIG. 10 is a flowchart showing an operating method of a battery management apparatus according to another embodiment. Operations S1010 to S1040 of FIG. 10 may be substantially the same as operations S810 to S840 of FIG. 8, and thus a redundant description thereof will be omitted.

Following operation S1040 of converting the voltage of the battery cell into the differential signal, operation S1050 of calculating a statistical value for the differential signal may be performed. In this case, the statistical value of the differential signal may be intended to identify the abnormal behavior of the battery in a sliding window (or moving window) manner. For example, the statistical value of the differential signal may include a standard deviation.

Next, operation S1060 of diagnosing that abnormality of the battery cell occurs when the statistical value for the differential signal is equal to or greater than a preset reference value may be performed. More specifically, the abnormality diagnosing unit 230 may diagnose that an abnormal voltage drop occurs in the battery cell when the statistical value of the differential signal of a battery voltage is equal to or greater than a preset reference value.

Although not shown, an operation of storing the measured voltage of the battery cell, the differential signal, etc., in the memory unit and/or an operation of generating a warning alarm when determining that abnormality occurs in the battery cell may be further provided. In this case, the warning alarm may be provided in the form of a message on a display unit (not shown), or light or a sound signal.

The operating method of the battery management apparatus according to the embodiment may be embodiment implemented in the form of an application or a program instruction that is executable through various computer components and recorded in a computer-readable recording medium. The computer-readable recording medium may include a program instruction, a data file, a data structure and the like solely or in a combined manner.

According to an embodiment described above, in a pre-processing process for converting data regarding a voltage of a battery into a differential signal, an optimal smoothing parameter determined according to a set algorithm, i.e., the smoothing parameter may be determined, which enables proper fitting with original data while reducing fluctuation of a curve of a smoothed differential signal. Moreover, it is possible to obtain a differential signal regarding a voltage of a battery (e.g., a voltage-capacity differential signal) by using an optimal smoothing parameter, accurately and easily detect an abnormal voltage drop phenomenon caused by an internal short-circuit of the battery based on the differential signal, and achieve a purpose such as battery deterioration quantification, abnormal deterioration identification, or the like.

So far, all components constituting the embodiment have been described as being combined or operating in combination, but it is not necessarily limited to this embodiment, and within the scope of the purpose, all components may be selectively combined with one or more to operate. Moreover, terms such as “include”, “constitute”, “have”, etc., described above may mean that the corresponding component may be inherent unless otherwise stated, and thus should be construed as further including other components rather than excluding other components.

The above description is merely illustrative of the technical idea of the present disclosure, and various modifications and variations will be possible without departing from the essential characteristics of embodiments of the present disclosure by those of ordinary skill in the art to which the embodiments disclosed herein pertains.

Therefore, the embodiments disclosed herein are intended for description rather than limitation of the technical spirit of the embodiments disclosed herein and the scope of the technical spirit of the present disclosure is not limited by these embodiments disclosed herein. The protection scope of the technical spirit disclosed herein should be interpreted by the following claims, and all technical spirits within the same range should be understood to be included in the range of the present disclosure.

1. A battery management apparatus comprising:
a voltage measuring unit configured to measure a voltage of a battery cell; and
a controller configured to sample raw data regarding the voltage of the battery cell in a designated unit to convert the raw data into original data in a monotonically increasing or monotonically decreasing form, smooth the original data into smoothed data by using an optimal smoothing parameter determined according to a set algorithm, and convert the smoothed data into a differential signal.

2. The battery management apparatus of claim 1, wherein the controller is further configured to determine the optimal smoothing parameter by using an algorithm of minimizing a cost function.

3. The battery management apparatus of claim 2, wherein the controller is further configured to:
obtain a differential signal set corresponding to the original data smoothed using at least one smoothing parameter of preset smoothing parameters; and
calculate the cost function based on a curve length of the differential signal set and a difference between the original data and the differential signal set.

4. The battery management apparatus of claim 3, wherein the controller is further configured to calculate a cost function value corresponding to the at least one smoothing parameter by multiplying a first variable that is a value obtained by linearly integrating a differential signal corresponding to the at least one smoothing parameter in a designated section by a second variable that is a root mean square (RMS) value of the difference between the original data and the differential signal corresponding to the at least one smoothing parameter.

5. The battery management apparatus of claim 4, wherein the controller is further configured to determine a smoothing parameter that minimizes a corresponding cost function value among the preset smoothing parameters.

6. The battery management apparatus of claim 5, wherein each of the preset smoothing parameters is a smoothing parameter in which a peak value of a corresponding differential signal does not exceed a designated value.

7. The battery management apparatus of claim 1, wherein the controller is further configured to classify capacity values of the battery cell having a same voltage magnitude and calculate an average value of the capacity values of the battery cell for each voltage magnitude to perform sampling with respect to the voltage of the battery cell.

8. The battery management apparatus of claim 1, wherein the controller is further configured to perform smoothing of the original data by using a smoothing algorithm to which a hyper parameter is applied such that a slope of the voltage of the battery cell satisfies continuity between adjacent data points.

9. The battery management apparatus of claim 1, further comprising an abnormality diagnosing unit configured to calculate a statistical value for the differential signal and diagnose that an abnormality of the battery cell occurs when the statistical value for the differential signal is equal to or greater than a preset reference value.

10. The battery management apparatus of claim 1, wherein the differential signal is a voltage-capacity differential signal or a voltage-time differential signal of the battery cell.

11. An operating method of a battery management apparatus, the operating method comprising:
measuring a voltage of a battery cell;
sampling raw data regarding the voltage of the battery cell in a designated unit to convert the raw data into original data in a monotonically increasing or monotonically decreasing form;
smoothing the original data into smoothed data by using an optimal smoothing parameter determined according to a set algorithm; and
converting the smoothed data into a differential signal.

12. The operating method of claim 11, wherein the smoothing of the original data comprises determining the optimal smoothing parameter by using an algorithm of minimizing a cost function.

13. The operating method of claim 12, wherein the determining of the optimal smoothing parameter comprises:
smoothing the original data by using at least one smoothing parameter of preset smoothing parameters;
obtaining a differential signal set corresponding to each smoothing parameter based on the smoothed original data; and
calculating the cost function based on a curve length of the differential signal set and a difference between the original data and the differential signal set.

14. The operating method of claim 13, wherein the calculating of the cost function comprises calculating a cost function value corresponding to the at least one smoothing parameter by multiplying a first variable that is a value obtained by linearly integrating a differential signal corresponding to the at least one smoothing parameter in a designated section by a second variable that is a root mean square (RMS) value of a difference between the original data and the differential signal corresponding to the at least one smoothing parameter.

15. The operating method of claim 14, wherein the determining of the optimal smoothing parameter further comprises determining a smoothing parameter that minimizes a corresponding cost function value among the preset smoothing parameters.

16. The operating method of claim 15, wherein each of the preset smoothing parameters is a smoothing parameter in which a peak value of a corresponding differential signal does not exceed a designated value.

17. The operating method of claim 11, wherein the sampling of the raw data regarding the voltage in the designated unit to convert the raw data into the original data in the monotonically increasing or monotonically decreasing form comprises classifying capacity values of the battery cell having a same voltage magnitude and calculating an average value of the capacity values of the battery cell for each voltage magnitude to perform sampling with respect to the voltage of the battery cell.

18. The operating method of claim 11, wherein the smoothing of the original data comprises performing smoothing by using a smoothing algorithm to which a hyper parameter is applied such that a slope of the voltage of the battery cell satisfies a continuity between adjacent data points.

19. The operating method of claim 11, further comprising:
calculating a statistical value for the differential signal; and
diagnosing that an abnormality of the battery cell occurs when the statistical value for the differential signal is equal to or greater than a preset reference value.

20. The operating method of claim 11, wherein the differential signal is a voltage-capacity differential signal or a voltage-time differential signal of the battery cell.
